(19) United States
(12) Patent Application Publication
(10) Pub. No.: US 2025/0004058 A1
(43) Pub. Date: Jan. 2, 2025

(54) FLOW BATTERY TESTING DEVICE

(71) Applicant: VRB Energy Operations (Beijing) Co., Ltd., Beijing (CN)

(72) Inventors: Hao Yang, Beijing (CN); Zhiling Zhao, Beijing (CN); Xingsheng Zhou, Beijing (CN); Huichao Liu, Beijing (CN); Qiming Ge, Beijing (CN)

(21) Appl. No.: 18/744,315

(22) Filed: Jun. 14, 2024

(30) Foreign Application Priority Data
Jun. 30, 2023 (CN) 202321718253.3

(51) Int. Cl. G01R 31/385; G01R 31/36

(52) U.S. Cl. CPC G01R 31/385; G01R 31/3644

(57) ABSTRACT

The present application provides a flow battery testing device, including a housing and a testing body. The testing body includes a testing stack and a plurality of liquid path assemblies. The testing stack is provided with a plurality of liquid flow paths. An outer surface of the housing is provided with a bearing surface, and the testing stack is provided on the bearing surface. The plurality of liquid path assemblies are provided in the housing, and correspondingly cyclically communicate with the plurality of liquid flow paths one to one. By using a miniaturized flow battery testing device to replace an actual flow battery for relevant testing, it is possible to achieve test results equivalent to those of the actual flow battery, thus effectively reducing testing difficulty.

### RELATED APPLICATIONS

This application claims priority to Chinese Patent Application No. 202321718253.3, filed Jun. 30, 2023, and titled FLOW BATTERY TESTING DEVICE, which is incorporated herein by reference in its entirety.

### TECHNICAL FIELD

The present application relates to, but is not limited to, the technical field of stack equipment, and specifically relates to a flow battery testing device.

### BACKGROUND

Flow batteries, as an indispensable part in the new clean energy industry, serve as an important bridge to connect the power grid and the user end in the photovoltaic and wind energy fields. Flow batteries store electrical energy from the grid side and output it to the user end, so their stability, safety, energy conversion rate, and storage capacity have become the direction of continuous research and development for various battery manufacturers.

At present, mainstream flow batteries each include a liquid tank for storing electrolyte, a stack, a liquid supply pipeline, a liquid return pipeline, and a liquid pump. In order to achieve sufficient electrical energy reserves, each part has a large volume, and the assembled flow battery is usually installed inside an engineering container, and then transported as a whole to the project site for relevant testing. During testing, it is extremely difficult to adjust and modify the flow battery in the case of data errors or parameter discrepancies. In addition, due to the large volume of a single flow battery, the volume of a plurality of flow batteries is even larger, and when it is necessary to conduct relevant tests on the plurality of flow batteries, most enterprises cannot provide a site that can accommodate the plurality of flow batteries.

### SUMMARY

The present application provides a flow battery testing device used to replace an actual flow battery for relevant testing. The testing process is easy to perform and can achieve test results equivalent to those of the actual flow battery.

An embodiment of the present utility model provides a flow battery testing device, comprising a housing and a testing body, the testing body comprising a testing stack and a plurality of liquid path assemblies, the testing stack being provided with a plurality of liquid flow paths, an outer surface of the housing being provided with a bearing surface, the testing stack being provided on the bearing surface, and the plurality of liquid path assemblies being provided in the housing and correspondingly cyclically communicating with the plurality of liquid flow paths one to one.

In some exemplary embodiments, the testing stack comprises two end plates, a plurality of flow channel frame assemblies provided between the two end plates, and a proton exchange membrane provided between adjacent flow channel frame assemblies, the two end plates are provided with a plurality of liquid inlet pipes correspondingly communicating with the plurality of flow channel frame assemblies one to one and a plurality of liquid outlet pipes correspondingly communicating with the plurality of flow channel frame assemblies one to one, and each flow channel frame assembly, together with the liquid inlet pipe and the liquid outlet pipe communicating therewith, forms one of the liquid flow paths.

In some exemplary embodiments, each flow channel frame assembly comprises a flow channel frame and a carbon felt provided inside the flow channel frame, and the proton exchange membrane is replaceably provided between adjacent flow channel frames.

In some exemplary embodiments, each liquid path assembly comprises a liquid tank, a liquid pump, a liquid supply pipeline and a liquid return pipeline, an inlet of the liquid supply pipeline is connected with an outlet of the liquid tank, an outlet of the liquid return pipeline is connected with an inlet of the liquid tank, and the liquid pump is provided at the liquid supply pipeline or the liquid return pipeline.

In some exemplary embodiments, the liquid pump is a centrifugal pump, and the centrifugal pump is provided at the liquid supply pipeline.

In some exemplary embodiments, the housing is provided with a plurality of liquid drain pipes, and the plurality of liquid drain pipes correspondingly communicate with the plurality of liquid tanks one to one through a plurality of switching valves.

In some exemplary embodiments, the bearing surface is located on a top surface of the housing.

In some exemplary embodiments, the flow battery testing device further comprises: a tray provided on the bearing surface, the testing stack being provided on the tray.

In some exemplary embodiments, the tray is bonded to the bearing surface.

In some exemplary embodiments, the plurality of liquid path assemblies are two liquid path assemblies, and the plurality of liquid flow paths are two liquid flow paths.

According to the technical solutions provided in the embodiments of the present utility model, by using a miniaturized flow battery testing device to replace an actual flow battery for relevant testing, it is possible to achieve test results equivalent to those of the actual flow battery, thus effectively reducing testing difficulty.

### BRIEF DESCRIPTION OF THE DRAWINGS

FIG. 1 illustrates a schematic perspective structural diagram of a flow battery testing device provided in some embodiments.

FIG. 2 illustrates a schematic exploded structural diagram of the flow battery testing device shown in FIG. 1.

The list of components in the drawings represented by respective reference signs is as follows:

100-Housing, 110-bearing surface, 120-liquid drain pipe, 130-connecting side surface, 140-upper table surface, 200-testing stack, 210-end plate, 211-liquid inlet pipe, 212-liquid outlet pipe, 300-liquid path assembly, 310-liquid tank, 320-liquid pump, 330-liquid supply pipeline, 340-liquid return pipeline, 400-tray

### DETAILED DESCRIPTION

The technical solutions in the embodiments of the present application will be described below clearly and completely with reference to the drawings in the embodiments of the present utility model. Obviously, the described embodiments are only a part of the embodiments of the present utility model instead of all of them. Based on the embodiments of the present utility model, all other embodiments obtained by those skilled in the art without exercising any inventive effort should still fall within the scope of protection of the present utility model.

It should be noted that all directional indicators (such as up, down, left, right, front, back . . . ) in the embodiments of the present utility model are only used to explain the relative position relationship, motion situation, etc. between components in a specific orientation (as shown in the drawings). If the specific orientation changes, the directional indicators also change accordingly.

In addition, in the present utility model, descriptions involving “first”, “second” and the like are only used for descriptive purposes and cannot be understood as indicating or implying their relative importance or implying the number of the indicated technical features. Therefore, a feature defined by “first” or “second” may explicitly or implicitly include at least one such feature. In the description of the present utility model, “a plurality of” means at least two, such as two, three, etc., unless otherwise specified.

In the present utility model, unless otherwise specified and defined, the terms “connect”, “fix” and the like should be broadly understood. For example, “fix” may refer to a fixed connection, a detachable connection, or an integral formation; and may be a mechanical connection or an electrical connection; “connect” may refer to a direct connection, an indirect connection through an intermediate medium, the communication within two components or the interaction between two components, unless otherwise specified. Those skilled in the art could understand the specific meanings of the above terms in the present utility model according to specific circumstances.

In addition, the technical solutions in various embodiments of the present utility model may be combined with each other, but must be based on what those skilled in the art can achieve. When the combination of technical solutions contradicts each other or cannot be achieved, such a combination of technical solutions should be deemed non-existent and not within the scope of protection of the present utility model.

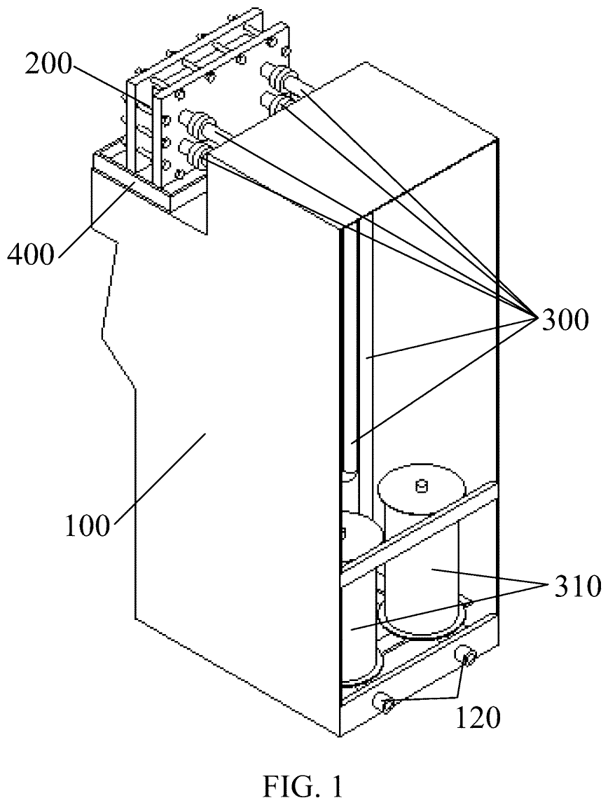

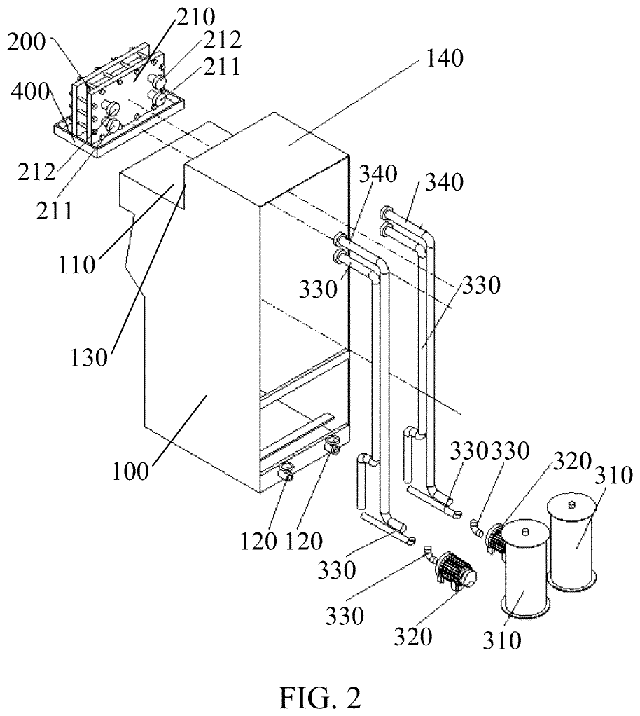

An embodiment of the present utility model provides a flow battery testing device. As shown in FIG. 1 and FIG. 2, the flow battery testing device includes a housing 100 and a testing body. The testing body includes a testing stack 200 and a plurality of liquid path assemblies 300. The testing stack 200 is provided with a plurality of liquid flow paths. An outer surface of the housing 100 is provided with a bearing surface 110. The testing stack 200 is provided on the bearing surface 110. The plurality of liquid path assemblies 300 are provided in the housing 100, and correspondingly cyclically communicate with the plurality of liquid flow paths one to one. The ratio of the size of the testing body to the size of the actual flow battery is set to 1:K, where K>1.

Since the ratio of the size of the testing body to the size of the actual flow battery is set to 1:K, where K>1, by using a miniaturized flow battery testing device to replace the actual flow battery for relevant testing, it is possible to achieve test results equivalent to those of the actual flow battery, thus effectively reducing testing difficulty.

Those skilled in the art can appropriately select K as needed. The appropriate selection of K reduces the size of the produced flow battery testing device, so that the device can be placed in a laboratory site for relevant testing, thus effectively reducing testing difficulty.

For example, the length of the housing is 500-2800 mm, the width of the housing is 760-3200 mm, and the height of the housing is 1300-2500 mm; the length of the testing stack 200 is 500-2680 mm, the width of the testing stack 200 is 300-2530 mm, and the height of the testing stack 200 is 310-1060 mm.

In some examples, as shown in FIG. 1 and FIG. 2, the testing stack 200 includes two end plates 210, a plurality of flow channel frame assemblies provided between the two end plates 210, and a proton exchange membrane provided between adjacent flow channel frame assemblies. The two end plates 210 are provided with a plurality of liquid inlet pipes 211 correspondingly communicating with the plurality of flow channel frame assemblies one to one and a plurality of liquid outlet pipes 212 correspondingly communicating with the plurality of flow channel frame assemblies one to one, and each flow channel frame assembly, together with the liquid inlet pipe 211 and the liquid outlet pipe 212 communicating therewith, forms one of the liquid flow paths.

In some embodiments, as shown in FIG. 1 and FIG. 2, the plurality of flow channel frame assemblies are two channel frame assemblies, the plurality of liquid flow paths are two liquid flow paths, and the plurality of liquid path assemblies 300 are two liquid path assemblies. The two end plates 210 are connected through bolts. The two flow channel frame assemblies are held and fixed between the two end plates 210. The two liquid inlet pipes 211 correspondingly communicate with the two flow channel frame assemblies one to one. The two liquid outlet pipes 212 also correspondingly communicate with the two flow channel frame assemblies one to one. One of the two channel frame assemblies is supplied with positive electrolyte by one of the liquid path assemblies 300, and the other is supplied with negative electrolyte by the other liquid path assembly 300.

In some examples, each flow channel frame assembly includes a flow channel frame and a carbon felt provided inside the flow channel frame, and the proton exchange membrane is replaceably provided between adjacent flow channel frames and used for preventing mixing between the two electrolytes (positive electrolyte and negative electrolyte) respectively supplied into the two flow channel frames.

In some example, as shown in FIG. 2, each liquid path assembly 300 includes a liquid tank 310, a liquid pump 320, a liquid supply pipeline 330 and a liquid return pipeline 340. An inlet of the liquid supply pipeline 330 is connected with an outlet of the liquid tank 310, an outlet of the liquid return pipeline 340 is connected with an inlet of the liquid tank 310, and the liquid pump 320 is provided at the liquid supply pipeline 330 or the liquid return pipeline 340. An outlet of the liquid supply pipeline 330 and an inlet of the liquid return pipeline 340 are connected with the corresponding liquid inlet pipe 211 and liquid outlet pipe 212. In some embodiments, the liquid pump 320 is configured to be a centrifugal pump, and the centrifugal pump is provided at the liquid supply pipeline 330.

In some examples, as shown in FIG. 1 and FIG. 2, the housing 100 is provided with two liquid drain pipes 120, the two liquid drain pipes 120 are located below the two liquid tanks 310, and the two liquid drain pipes 120 correspondingly communicate with the two liquid tanks 310 one to one through two switching valves. When a switching valve is opened, the electrolyte in the liquid tank 310 communicating with the switching valve is drained sequentially through the switching valve and the liquid drain pipe 120 communicating with the switching valve.

In some examples, as shown in FIG. 1 and FIG. 2, the bearing surface 110 is located on a top surface of the housing 100. The top surface of the housing 100 may be a stepped surface having a lower table surface, a connecting side surface 130 and an upper table surface 140, and the bearing surface 110 is the lower table surface. The outlet of the liquid supply pipeline 330 and the inlet of the liquid return pipeline 340 pass through the connecting side surface 130 inside the housing 100 and extend to the outside of the housing 100 to be connected with the testing stack 200.

In some examples, as shown in FIG. 1 and FIG. 2, the flow battery testing device further includes a tray 400. The tray 400 is provided on the bearing surface 110, and the testing stack 200 is detachably provided on the tray 400. The tray 400 may be bonded to the bearing surface 110; or the tray 400 may be fixed to the bearing surface 110 through screws, or the like. The above means can all achieve the purpose of the present application, and do not deviate from the design concept of the present utility model, which will not be repeated here and all fall within the scope of protection of the present application.

To sum up, according to the technical solutions provided in the embodiments of the present utility model, by using a miniaturized flow battery testing device to replace an actual flow battery for relevant testing, it is possible to achieve test results equivalent to those of the actual flow battery, thus effectively reducing testing difficulty.

Although the embodiments of the present application are shown and described above, it can be understood that the above embodiments are exemplary and cannot be understood as limitations to the present application. Those skilled in the art may make changes, modifications, replacements and variations to the above embodiments within the scope of protection of the present application.

1. A flow battery testing device, characterized by: comprising a housing and a testing body, the testing body comprising a testing stack and a plurality of liquid path assemblies, the testing stack being provided with a plurality of liquid flow paths, an outer surface of the housing being provided with a bearing surface, the testing stack being provided on the bearing surface, and the plurality of liquid path assemblies being provided in the housing and correspondingly cyclically communicating with the plurality of liquid flow paths one to one.

2. The flow battery testing device according to claim 1, wherein the testing stack comprises two end plates, a plurality of flow channel frame assemblies provided between the two end plates, and a proton exchange membrane provided between adjacent flow channel frame assemblies, the two end plates are provided with a plurality of liquid inlet pipes correspondingly communicating with the plurality of flow channel frame assemblies one to one and a plurality of liquid outlet pipes correspondingly communicating with the plurality of flow channel frame assemblies one to one, and each flow channel frame assembly, together with the liquid inlet pipe and the liquid outlet pipe communicating therewith, forms one of the liquid flow paths.

3. The flow battery testing device according to claim 2, wherein each flow channel frame assembly comprises a flow channel frame and a carbon felt provided inside the flow channel frame, and the proton exchange membrane is replaceably provided between adjacent flow channel frames.

4. The flow battery testing device according to claim 1, wherein each liquid path assembly comprises a liquid tank, a liquid pump, a liquid supply pipeline and a liquid return pipeline, an inlet of the liquid supply pipeline is connected with an outlet of the liquid tank, an outlet of the liquid return pipeline is connected with an inlet of the liquid tank, and the liquid pump is provided at the liquid supply pipeline or the liquid return pipeline.

5. The flow battery testing device according to claim 4, wherein the liquid pump is a centrifugal pump, and the centrifugal pump is provided at the liquid supply pipeline.

6. The flow battery testing device according to claim 4, wherein the housing is provided with a plurality of liquid drain pipes, and the plurality of liquid drain pipes correspondingly communicate with the plurality of liquid tanks one to one through a plurality of switching valves.

7. The flow battery testing device according to claim 1, wherein the bearing surface is located on a top surface of the housing.

8. The flow battery testing device according to claim 1, wherein the flow battery testing device further comprises:
a tray provided on the bearing surface, the testing stack being provided on the tray.

9. The flow battery testing device according to claim 8, wherein the tray is bonded to the bearing surface.

10. The flow battery testing device according to claim 1, wherein the plurality of liquid path assemblies are two liquid path assemblies, and the plurality of liquid flow paths are two liquid flow paths.
